(19) United States
(12) Patent Application Publication
(10) Pub. No.: US 2024/0413104 A1
(43) Pub. Date: Dec. 12, 2024

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Sang Cheon PARK, Suwon-si (KR); Ji-Seok HONG, Suwon-si (KR); Un-Byoung KANG, Suwon-si (KR); Ku Young KIM, Suwon-si (KR)

(73) Assignee: Samsung Electronics Co., Ltd., Suwon-si (KR)

(21) Appl. No.: 18/425,173

(22) Filed: Jan. 29, 2024

(30) Foreign Application Priority Data
Jun. 9, 2023 (KR) 10-2023-0074308
Sep. 12, 2023 (KR) 10-2023-0120863

(51) Int. Cl. H01L 23/00; H01L 23/528; H01L 25/18; H10B 80/00

(52) U.S. Cl. CPC H01L 24/02; H01L 23/528; H01L 24/05; H01L 24/06; H01L 24/08; H01L 25/18; H10B 80/00; H01L 24/16; H01L 24/32; H01L 24/73; H01L 2224/02145; H01L 2224/02255; H01L 2224/0557; H01L 2224/05624; H01L 2224/05644; H01L 2224/05647; H01L 2224/05655; H01L 2224/05669; H01L 2224/05684; H01L 2224/06181; H01L 2224/06517; H01L 2224/08145; H01L 2224/16227; H01L 2224/32225; H01L 2224/73204; H01L 2924/1431; H01L 2924/1436; H01L 2924/1437; H01L 2924/1441; H01L 2924/1443

(57) ABSTRACT

There is provided a semiconductor device with improved product reliability. The semiconductor device includes a substrate, a structure on the substrate and including multilayer metal patterns and multilayer insulating layers, and a pad layer on the structure and including a plurality of bonding pads, wherein a plurality of uppermost patterns at an uppermost layer among the multilayer metal patterns include electrode patterns for transferring signals and alleviation patterns that do not transfer the signals, a first ratio of the alleviation patterns within a first reference shape at a first distance from an edge of the structure is greater than a second ratio of the alleviation patterns within a second reference shape at a second distance from the edge of the structure, and the first distance is greater than the second distance.

### CROSS-REFERENCE TO RELATED APPLICATION

This application claims priority from Korean Patent Application No. 10-2023-0074308 filed on Jun. 9, 2023, and No. 10-2023-0120863 filed on Sep. 12, 2023, in the Korean Intellectual Property Office, and all the benefits accruing therefrom under 35 U.S.C. 119, the contents of each of which in its entirety are herein incorporated by reference.

### BACKGROUND

### 1. Technical Field

The present disclosure relates to semiconductor devices and semiconductor packages including the same.

### 2. Description of the Related Art

As the electronics industry develops highly, the demand for high integration of semiconductor devices has been gradually intensified. Accordingly, various problems such as a decrease in process margin of an exposure process of defining fine patterns have occurred, making it increasingly difficult to implement semiconductor devices. In addition, with the development of the electronics industry, the demand for high speed of the semiconductor devices has been gradually intensified. Various researches have been conducted in order to meet the demands for high integration and/or high speed of the semiconductor devices.

### SUMMARY

Some example embodiments of the present disclosure provide semiconductor devices with improved product reliability.

Some example embodiments of the present disclosure provide semiconductor packages with improved product reliability.

However, example embodiments of the present disclosure are not restricted to those set forth herein. The above and other aspects of the present disclosure will become more apparent to one of ordinary skill in the art to which the present disclosure pertains by referencing the detailed description of the present disclosure given below.

According to an example embodiment, a semiconductor device may include a substrate, a structure on the substrate, the structure including multilayer metal patterns and multilayer insulating layers, and a pad layer on the structure, the pad layer including a plurality of bonding pads, wherein a plurality of uppermost patterns at an uppermost level among the multilayer metal patterns include electrode patterns configured to transfer signals and alleviation patterns configured to not transfer signals, a first ratio of the alleviation patterns within a first reference shape at a first distance from an edge of the structure is greater than a second ratio of the alleviation patterns within a second reference shape at a second distance from the edge of the structure, and the first distance is greater than the second distance.

According to an example embodiment, a semiconductor device may include a substrate, a structure on the substrate, the structure including multilayer metal patterns and multilayer insulating layers, and a pad layer on the structure, the pad layer including a plurality of bonding pads, wherein the structure includes a center region and a peripheral region surrounding the center region, a plurality of uppermost patterns at an uppermost level among the multilayer metal patterns include a plurality of electrode patterns configured to transfer signals and a plurality of alleviation patterns configured to not transfer signals, the plurality of electrode patterns include a plurality of first electrode patterns on one side and a plurality of second electrode patterns on the opposite side, with respect to a plurality of first alleviation patterns therebetween, the plurality of alleviation patterns include a plurality of second alleviation patterns in the peripheral region, a first ratio of the first electrode patterns within a first reference shape in the center region is the same as a second ratio of the second electrode patterns within a second reference shape in the center region, and the first ratio of the first electrode patterns within the first reference shape in the center region is greater than a third ratio of the second alleviation patterns within a third reference shape in the peripheral region.

According to an example embodiment, a semiconductor device may include a first chip including a first bonding pad and a first pad insulating film surrounding the first bonding pad, and a second chip including a second bonding pad and a second pad insulating film surrounding the second bonding pad, wherein the first chip and the second chip are hybrid-bonded to each other such that the first bonding pad and the second bonding pad are in direct contact with each other and the first pad insulating film and the second pad insulating film are in direct contact with each other, the first chip includes: a substrate, a structure on the substrate, the structure including multilayer metal patterns and multilayer insulating layers, and a pad layer on the structure, the pad layer including a plurality of bonding pads, a plurality of uppermost patterns at an uppermost level among the multilayer metal patterns include electrode patterns configured to transfer signals and alleviation patterns configured to not transfer signals, a first ratio of the alleviation patterns within a first reference shape at a first distance from an edge of the structure is greater than a second ratio of the alleviation patterns within a second reference shape at a second distance from the edge of the structure, and the first distance is greater than the second distance.

Detailed contents of some example embodiments are described in a detailed description and are illustrated in the drawings.

### BRIEF DESCRIPTION OF THE DRAWINGS

The above and other aspects and features of the present disclosure will become more apparent by describing in detail some example embodiments thereof with reference to the attached drawings, in which:

FIG. 1 is a cross-sectional view for describing a semiconductor device according to an example embodiment of the present disclosure;

FIG. 2 is an enlarged view of region A of FIG. 1;

FIG. 3 is a plan view for describing an arrangement of electrode patterns and alleviation patterns illustrated in FIG. 1;

FIG. 4 is a view for describing a ratio of patterns defined within a reference shape;

FIG. 5 is a view for describing region B of FIG. 3;

FIG. 6 is a view for describing an amount of change in a ratio of patterns in FIG. 5;

FIG. 7 is a view for describing region C of FIG. 3;

FIG. 8 is a view for describing an amount of change in a ratio of patterns in FIG. 7;

FIG. 9 is a view for describing a semiconductor device according to an example embodiment of the present disclosure;

FIG. 10 is a view for describing an amount of change in a ratio of patterns in FIG. 9;

FIG. 11 is a view for describing a semiconductor device according to an example embodiment of the present disclosure;

FIGS. 12 and 13 are views for describing a semiconductor device according to an example embodiment of the present disclosure;

FIG. 14 is a view for describing a semiconductor package according to an example embodiment of the present disclosure;

FIG. 15 is a view for describing a semiconductor package according to an example embodiment of the present disclosure; and

FIGS. 16 and 17 are intermediate step views for describing a semiconductor device according to an example embodiment of the present disclosure.

### DETAILED DESCRIPTION

Hereinafter, some example embodiments of the present disclosure will be described in detail with reference to the accompanying drawings. The same components in the drawings will be denoted by the same reference numerals, and an overlapping description thereof will be omitted.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

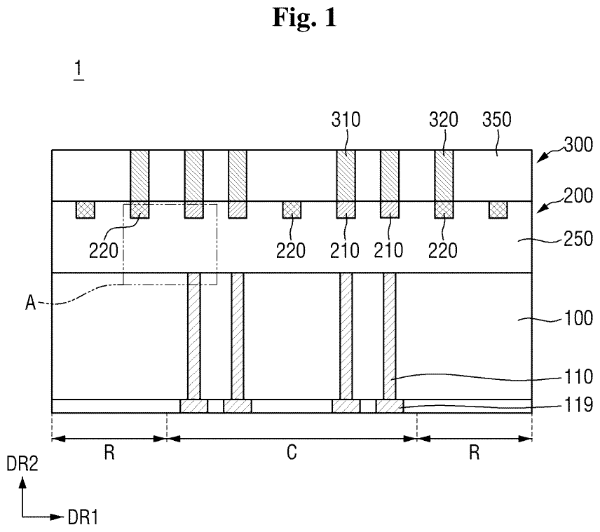

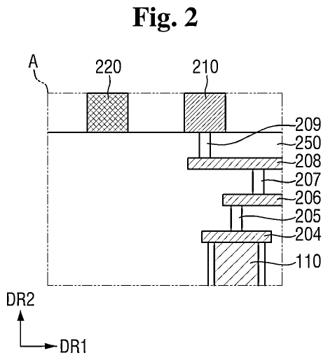

FIG. 1 is a cross-sectional view for describing a semiconductor device according to an example embodiment of the present disclosure. FIG. 2 is an enlarged view of region A of FIG. 1.

First, referring to FIG. 1, a semiconductor device 1 according to the present disclosure includes a substrate 100, through silicon vias 110, a structure 200, a pad layer 300, and the like.

The semiconductor device 1 may be a memory chip, but example embodiments are not limited thereto. For example, the semiconductor device 1 may be a volatile memory semiconductor chip such as a dynamic random access memory (DRAM) or a static random access memory (SRAM) or a non-volatile memory semiconductor chip such as a phase-change random access memory (PRAM), a magnetoresistive random access memory (MRAM), a ferroelectric random access memory (FeRAM), or a resistive random access memory (RRAM).

The substrate 100 may be, for example, bulk silicon or silicon-on-insulator (SOI). The substrate 100 may include silicon germanium, silicon germanium on insulator (SGOI), indium antimonide, a lead tellurium compound, indium arsenide, indium phosphide, gallium arsenide, or gallium antimonide, but example embodiments are not limited thereto.

Connection pads 119 may be disposed on a lower surface of the substrate 100. Although not separately illustrated, connection pads may also be disposed on an upper surface of the substrate 100. Each of such connection pads 119 may include, for example, at least one of aluminum (Al), copper (Cu), nickel (Ni), tungsten (W), platinum (Pt), gold (Au), or combinations thereof, but example embodiments are not limited thereto.

In addition, the substrate 100 may be divided into a center region C and a peripheral region R surrounding the center region C.

The through silicon vias 110 may penetrate through the substrate 100. The through silicon vias 110 may have a pillar shape extending in a second direction DR2, and electrically connecting the connection pad 119 disposed on the lower surface of the substrate 100 and the connection pads disposed on the upper surface of the substrate 100 to each other. A plurality of through silicon vias 110 may be disposed to be spaced apart from each other in a first direction DR1. The through silicon vias 110 may be disposed in the center region C and may not be disposed in the peripheral region R, but are not limited thereto.

For example, the through silicon via 110 may include a barrier film formed on a surface of the pillar shape and a buried conductive layer filling an inner portion of the barrier film. The barrier film may include at least one of Ti, TiN, Ta, TaN, Ru, Co, Mn, WN, Ni, or NiB, but example embodiments are not limited thereto. The buried conductive layer may include at least one of Cu, Cu alloys such as CuSn, CuMg, CuNi, CuZn, CuPd, CuAu, CuRe, and CuW, W, W alloys, Ni, Ru, or Co, but example embodiments are not limited thereto.

An insulating film may be interposed between the through silicon via 110 and the substrate 100. The insulating film may include an oxide film, a nitride film, a carbide film, a polymer, or combinations thereof, but example embodiments are not limited thereto.

The structure (or a wiring structure) 200 may be disposed on the substrate 100. For example, the structure 200 may be disposed on the upper surface of the substrate 100 in the second direction DR2.

As illustrated in FIG. 2, the structure 200 includes a plurality of metal patterns (or wiring patterns) 204, 206, 208, 210, and 220 that are stacked and a plurality of insulating layers 250 that are stacked. In addition, the structure 200 includes vertical wiring (or vias) 205, 207, and 209 for electrically connecting the metal patterns 204, 206, 208, and 210 that are stacked to each other.

As illustrated in FIG. 2, a thickness of the uppermost patterns 210 and 220 disposed at the uppermost level among the plurality of metal patterns 204, 206, 208, 210, and 220 may be greater than thicknesses of the metal patterns 208, 206, and 204 disposed below the uppermost layer.

The uppermost patterns 210 and 220 include electrode patterns 210 and alleviation patterns 220.

The electrode pattern 210 is electrically connected to other metal patterns 204, 206, and 208 in order to transfer a signal. On the other hand, the alleviation pattern 220 is not used to transfer the signal, and thus, is not electrically connected to the other metal patterns 204, 206, and 208. Here, the signal may refer to at least one of, for example, a data signal, a control signal, and a power signal.

A shape of the structure 200 illustrated in FIG. 2 is illustrative, and example embodiments are not limited thereto.

As described later, the alleviation pattern 220 is used to alleviate curvature in topography of thinned chips bonded to each other by a hybrid bonding method. The alleviation pattern 220 is used to minimize a void between stacked chips.

Referring to FIG. 1 again, the pad layer 300 is disposed on the structure 200. The pad layer 300 includes a plurality of bonding pads 310 and a passivation layer (or a pad insulating film) 350. The bonding pad 310 is in direct contact with a corresponding electrode pad 210.

In addition, the pad layer 300 optionally includes a plurality of dummy pads 320. The dummy pad 320 is in direct contact with a corresponding alleviation pattern 220.

According to an example embodiment, the dummy pads 320 may be positioned on all of the alleviation patterns 220.

According to another example embodiment, as illustrated in FIG. 1, the dummy pads 320 may be positioned only on some of the alleviation patterns 220, and may not be positioned on the others of the alleviation patterns 220.

According to still another example embodiment, the dummy pads 320 may not be positioned on all of the alleviation patterns 220.

The bonding pad 310 and the dummy pad 320 may include the same metal. For example, the bonding pad 310 and the dummy pad 320 may include copper (Cu), but are not limited thereto. For example, the bonding pad 310 and the dummy pad 320 may include a material (e.g., gold) that may be bonded to copper.

The passivation layer 350 is disposed around the bonding pads 310 and the dummy pads 320 and exposes upper surfaces of the bonding pads 310 and the dummy pads 320. The passivation layer 350 may include, for example, silicon oxide (SiOx), but example embodiments are not limited thereto. For example, the passivation layer 350 may include a material (SiCN) that may be bonded to silicon oxide.

Here, the semiconductor device 1 may be bonded to another semiconductor device by hybrid Cu bonding. That is, the bonding pads 310 and the dummy pads 320 of the semiconductor device 1 are bonded to bonding pads and dummy pads of another semiconductor device, and the passivation layer of the semiconductor device 1 is bonded to a passivation layer of another semiconductor device.

When a plurality of semiconductor devices 1 (e.g., thinned chips) are stacked and bonded to each other using the hybrid Cu bonding as described above, as the number of stacked chips increases, voids (e.g., stack voids) may greatly increase. When a small number of (e.g., four or less) thinned chips are stacked, topography of the uppermost thinned chip may have a substantially smooth plane. However, as the number of stacked thinned chips increases (e.g., 8 or more), topography of the uppermost thinned chip may have a significantly great curvature. Topography having such great curvature greatly increases stack voids. The alleviation patterns 220 may serve to reduce or minimize the stack voids by alleviating the curvature of the topography.

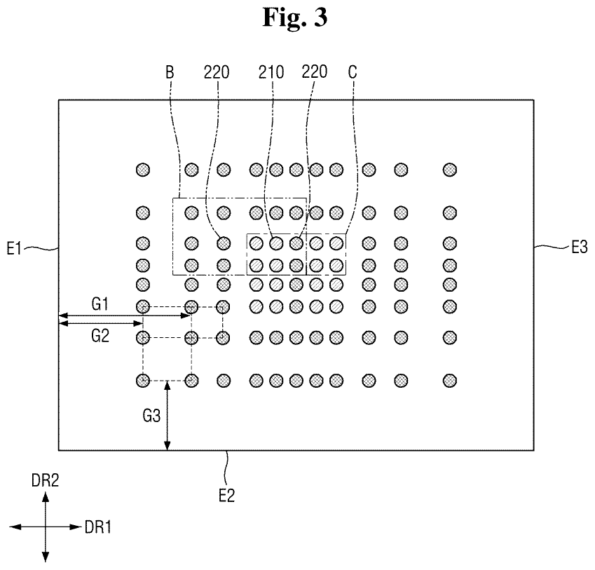

Here, an arrangement of such alleviation patterns 220 will be described using FIGS. 3 to 8.

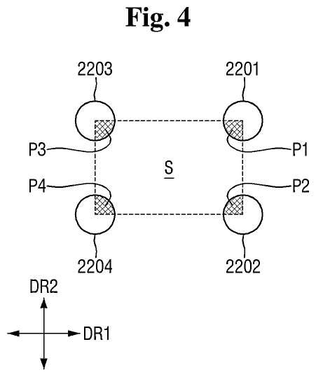

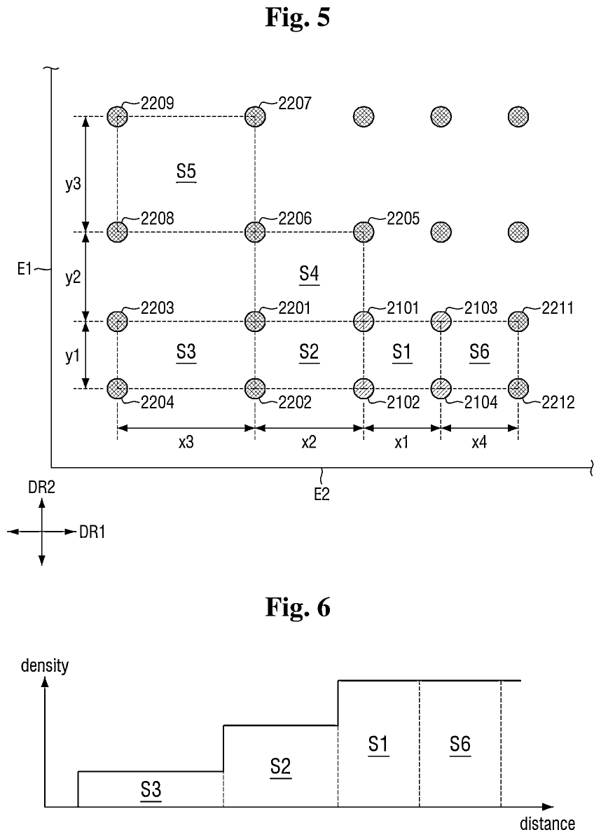

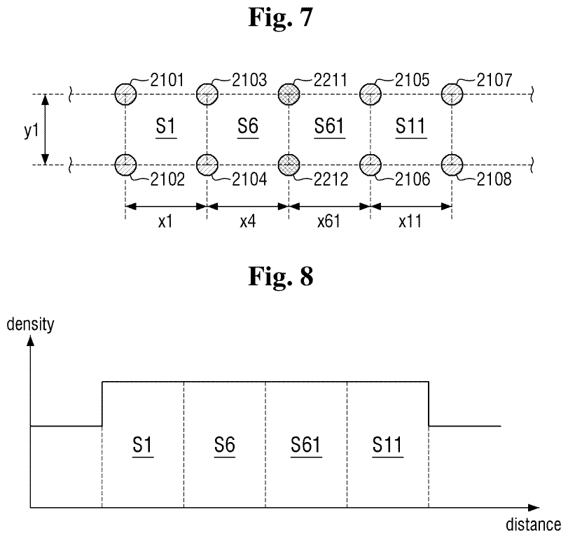

FIG. 3 is a plan view for describing an arrangement of electrode patterns and alleviation patterns illustrated in FIG. 1. FIG. 4 is a view for describing a ratio of patterns defined within a reference shape. FIG. 5 is a view for describing region B of FIG. 3. FIG. 6 is a view for describing an amount of change in a ratio of patterns in FIG. 5. FIG. 7 is a view for describing region C of FIG. 3. FIG. 8 is a view for describing an amount of change in a ratio of patterns in FIG. 7.

First, referring to FIG. 3, a plurality of electrode patterns 210 are disposed in a matrix form in the center region of the semiconductor device 1. That is, the plurality of electrode patterns 210 are disposed in the first direction DR1 and the second direction DR2.

In addition, as illustrated in FIG. 3, the plurality of electrode patterns 210 may be divided into two groups of which one is disposed on one side in the first direction DR1 and the other is disposed on the other side in the first direction DR1. The two groups are spaced apart from each other, and the alleviation patterns 220 may be disposed between the two groups.

In addition, a plurality of alleviation patterns 220 are disposed around the plurality of electrode patterns 210. As illustrated in FIG. 3, intervals between the plurality of alleviation patterns 220 may not be constant. For example, the intervals between the plurality of alleviation patterns 220 may increase from the plurality of electrode patterns 210 toward an outward direction.

In an example embodiment, installation positions of the alleviation patterns 220 may be changed depending on distances from edges E1, E2, and E3 of the structure 200.

In another example embodiment, a first ratio of the alleviation patterns 220 within a first reference shape positioned at a first distance G1 from an edge (e.g., E1) of the structure 200 is greater than a second ratio of the alleviation patterns 220 within a second reference shape positioned at a second distance G2 from the edge E1 of the structure 200. For example, the first and second reference shapes may be a rectangular shape with a respective alleviation pattern 220 located at each corner (e.g., at each vertices of the rectangular shape), as illustrated in FIG. 3.

Even considering a distance (e.g., G3) from another edge (e.g., E2), a ratio of alleviation patterns within a reference shape is changed as described above.

Here, referring to FIG. 4, a reference shape S is determined by an arrangement of the alleviation patterns 220. As illustrated in FIG. 4, the reference shape S may be a rectangle, but example embodiments are not limited thereto. The reference shape S may be, for example, a triangle, a pentagon, a hexagon, an octagon, or the like.

The phrase “ratio of patterns within the reference shape” refers to a ratio between a total area of the reference shape S and an area of the patterns (alleviation patterns and/or electrode patterns) positioned within the reference shape S. In FIG. 4, alleviation patterns 2201, 2202, 2203, and 2204 forming the rectangle will be described by way of example.

As illustrated in FIG. 4, when the centers of four alleviation patterns 2201, 2202, 2203, and 2204 are connected to each other, a virtual rectangle is obtained. A first distance between alleviation patterns (e.g., 2201 and 2203) adjacent to each other in the first direction DR1 and a second distance between alleviation patterns (e.g., 2201 and 2202) adjacent to each other in the second direction DR2 are calculated, and an area of the rectangle (e.g., a total area of the reference shape S) is obtained through the product of the first distance and the second distance.

In addition, the alleviation patterns 2201, 2202, 2203, and 2204 overlap the virtual rectangle. Regions P1, P2, P3, and P4 overlapping the alleviation patterns 2201, 2202, 2203, and 2204 are calculated. An area of the alleviation patterns 2201, 2202, 2203, and 2204 positioned within the reference shape S is the sum (e.g., P1+P2+P3+P4) of the overlapping regions P1, P2, P3, and P4.

Here, referring to FIG. 5, a reference shape S1 is defined by electrode patterns 2101, 2102, 2103, and 2104, and a reference shape S2 is defined by the electrode patterns 2101 and 2102 and alleviation patterns 2201 and 2202. In addition, a reference shape S3 is defined by alleviation patterns 2201, 2202, 2203, and 2204, and a reference shape S4 is defined by the electrode pattern 2101 and alleviation patterns 2201, 2205, and 2206. In addition, a reference shape S5 is defined by alleviation patterns 2206, 2207, 2208, and 2209. A reference shape S6 is defined by the electrode patterns 2103 and 2104 and alleviation patterns 2211 and 2212.

For example, the alleviation patterns 2211 and 2212 may be disposed at the center of the structure 200. That is, the alleviation patterns 2211 and 2212 are positioned at the same distance from both edges E1 and E3 of the structure 200.

A distance x1 between the adjacent electrode patterns 2101 and 2103 (or a transverse length of the reference shape S1) is smaller than a distance x2 between the electrode pattern 2101 and the alleviation pattern 2201 adjacent to the electrode pattern 2101 (or a transverse length of the reference shape S2). The distance x2 between the electrode pattern 2101 and the alleviation pattern 2201 adjacent to the electrode pattern 2101 is smaller than a distance x3 between the adjacent alleviation patterns 2201 and 2203 (or a transverse length of the reference shape S3).

A distance y1 between the adjacent alleviation patterns 2201 and 2202 (or a longitudinal length of the reference shape S2) is smaller than a distance y2 between the adjacent alleviation patterns 2201 and 2206 (or a longitudinal length of the reference shape S4). The distance y2 between the adjacent alleviation patterns 2201 and 2206 is smaller than a distance y3 between the adjacent alleviation patterns 2206 and 2207 (or a longitudinal length of the reference shape S5).

The distance x1 between the adjacent electrode patterns 2101 and 2103 and a distance x4 between the electrode pattern 2103 and the adjacent alleviation pattern 2211 adjacent to each other are the same as each other.

Based on such an arrangement, areas of the reference shapes S1 and S6 are the same as each other (S1=S6). When comparing areas of the reference shapes S1, S2, and S3 with each other, S3>S2>S1. In addition, when comparing areas of the reference shapes S1, S4, and S5 with each other, S5>S4>S1.

As illustrated in FIG. 5, the electrode patterns 2101, 2102, 2103, and 2104 and the alleviation patterns 2201, 2202, 2203, 2204, 2205, 2206, 2207, 2208, 2209, 2211, and 2212 may have substantially the same size.

Accordingly, a first ratio of the electrode patterns 2101, 2102, 2103, and 2104 in the reference shape S1 is greater than a second ratio of the electrode patterns 2101 and 2102 and the alleviation patterns 2201 and 2202 in the reference shape S2. Similarly, the second ratio of the electrode patterns 2101 and 2102 and the alleviation patterns 2201 and 2202 in the reference shape S2 is greater than a third ratio of the alleviation patterns 2201, 2202, 2203, and 2204 in reference shape S3.

That is, the farther from the edge E1 of the structure 200 (or the closer to the center of the structure 200), the greater the ratio. That is, “first ratio>second ratio>third ratio”.

In addition, the first ratio of the electrode patterns 2101, 2102, 2103, and 2104 in the reference shape S1 is greater than a fourth ratio of the electrode pattern 2101 and the alleviation patterns 2201, 2205, and 2206 in the reference shape S4. Similarly, the fourth ratio of the electrode pattern 2101 and the alleviation patterns 2201, 2205, and 2206 in the reference shape S4 is greater than a fifth ratio of the alleviation patterns 2206, 2207, 2208, and 2209 in reference shape S5.

That is, the farther from a corner of the structure 200 (or the closer to the center of the structure 200), the greater the ratio. That is, “first ratio>fourth ratio>fifth ratio”.

In addition, the first ratio of the electrode patterns 2101, 2102, 2103, and 2104 in the reference shape S1 and a sixth ratio of the electrode patterns 2103 and 2104 and the alleviation patterns 2211 and 2212 in the reference shape S6 are the same as each other. A plurality of reference shapes may be positioned in a specific region (e.g., the center region) within the structure 200, and ratios of patterns within the plurality of reference shapes within the specific region may be the same as each other.

In some example embodiments, when distances from the center of the structure 200 are the same as each other, the ratios may be the same as each other.

Here, referring to FIG. 6, an x-axis represents a distance from the edge E1, and a y-axis represents a ratio of patterns within the reference shape.

The closer from the edge E1 to the center of the structure 200, the greater the ratios of the patterns within the reference shapes. That is, the third ratio of the patterns within the reference shape S3<the second ratio of the patterns within the reference shape S2<the first ratio of the patterns within the reference shape S1.

Meanwhile, a ratio difference between reference shapes (e.g., S3 and S2) immediately adjacent to each other may be less than 53%. That is, a difference between the third ratio and the second ratio is less than 53%, and a difference between the second ratio and the first ratio is less than 53%.

When the ratio difference between the reference shapes (e.g., S2 and S3) immediately adjacent to each other as described above is less than 53%, curvature in the topography of the thinned chip may be significantly alleviated. Because a proportion of a metal material gradually decreases from the center of the structure 200 toward the edge, the topography of the thinned chip has small curvature. For example, the topography of the thinned chip has a smooth surface of which a height of the curvature is 87 Å or less. Accordingly, the voids between the stacked thinned chips may be reduced or minimized.

Here, referring to FIG. 7, the alleviation patterns 2211 and 2212 are disposed at the center of the structure 200. That is, the alleviation patterns 2211 and 2212 are positioned at the same distance from both edges E1 and E3 of the structure 200.

The reference shape S1 is defined by the electrode patterns 2101, 2202, 2103, and 2104, and the reference shape S6 is defined by the electrode patterns 2103 and 2104 and the alleviation patterns 2211 and 2212. A reference shape S61 is defined by electrode patterns 2105 and 2106 and the alleviation patterns 2211 and 2212, and a reference shape S11 is defined by electrode patterns 2105, 2106, 2107, and 2108.

The distance x1 between the electrode patterns 2101 and 2103 adjacent to each other and the distance x4 between the electrode pattern 2103 and the adjacent alleviation pattern 2211 are the same as each other. A distance x11 between the adjacent electrode patterns 2105 and 2107 and a distance x61 between the electrode pattern 2105 and the adjacent alleviation pattern 2211 are the same as each other.

Based on such an arrangement, areas of the reference shapes S1, S6, S61, and S11 are the same as each other (S1=S6=S61=S11).

Here, referring to FIG. 8, an x-axis represents a distance from the edge E1, and a y-axis represents a ratio of patterns within the reference shape. Ratios of the patterns in the reference shapes S1, S6, S61, and S11 existing in the center region of the structure 200 may be constant.

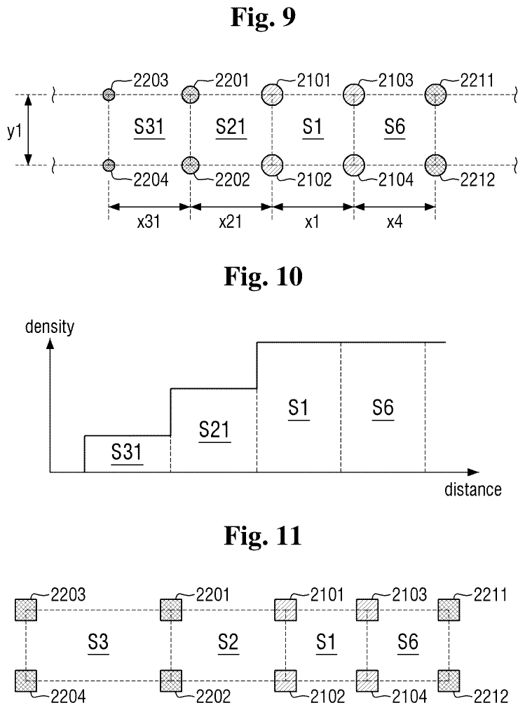

FIG. 9 is a view for describing a semiconductor device according to an example embodiment of the present disclosure. FIG. 10 is a view for describing an amount of change in a ratio of patterns in FIG. 9. Hereinafter, contents different from those described with reference to FIGS. 1 to 8 will be mainly described.

First, referring to FIG. 9, the distance x1 between the adjacent electrode patterns 2101 and 2103, a distance x21 between the electrode pattern 2101 and the alleviation pattern 2201 adjacent to the electrode pattern 2101, and a distance x31 between the adjacent alleviation patterns 2201 and 2203 are the same as each other.

Based on such an arrangement, areas of reference shapes S1, S21, S31, and S6 are the same as each other (S1=S21=S31=S6).

On the other hand, sizes of the alleviation patterns 2201 and 2202 distant from the edge E1 of the structure 200 may be greater than sizes of the alleviation patterns 2203 and 2204 close to the edge E1 of the structure 200. Sizes of the electrode patterns 2101 and 2102 distant from the edge E1 of the structure 200 may be greater than the sizes of the alleviation patterns 2201 and 2202 close to the edge E1 of the structure 200. On the other hand, sizes of the electrode patterns 2101, 2102, 2103, and 2104 and the alleviation patterns 2211 and 2212 existing in the center region of the structure 200 are the same as each other.

Based on such an arrangement and such pattern sizes, as illustrated in FIGS. 9 and 10, a first ratio of the electrode patterns 2101, 2102, 2103, and 2104 in the reference shape S1 is greater than a twenty-first ratio of the electrode patterns 2101 and 2102 and the alleviation patterns 2201 and 2202 in the reference shape S21. Similarly, the twenty-first ratio of the electrode patterns 2101 and 2102 and the alleviation patterns 2201 and 2202 in the reference shape S21 is greater than a thirty-first ratio of the alleviation patterns 2201, 2202, 2203, and 2204 in the reference shape S31.

FIG. 11 is a view for describing a semiconductor device according to an example embodiment of the present disclosure. Hereinafter, contents different from those described with reference to FIGS. 1 to 8 will be mainly described.

Referring to FIG. 11, the electrode patterns 2101, 2102, 2103, and 2104 and the alleviation patterns 2201, 2202, 2203, 2204, 2211, and 2212 may have a quadrangular shape, but are not limited thereto. For example, the electrode patterns 2101, 2102, 2103, and 2104 and the alleviation patterns 2201, 2202, 2203, 2204, 2211, and 2212 may also have a shape in which the vertices of quadrangles are chamfered.

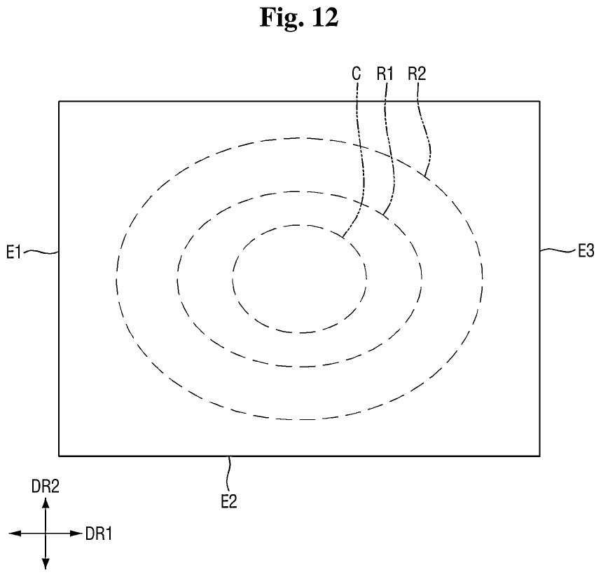

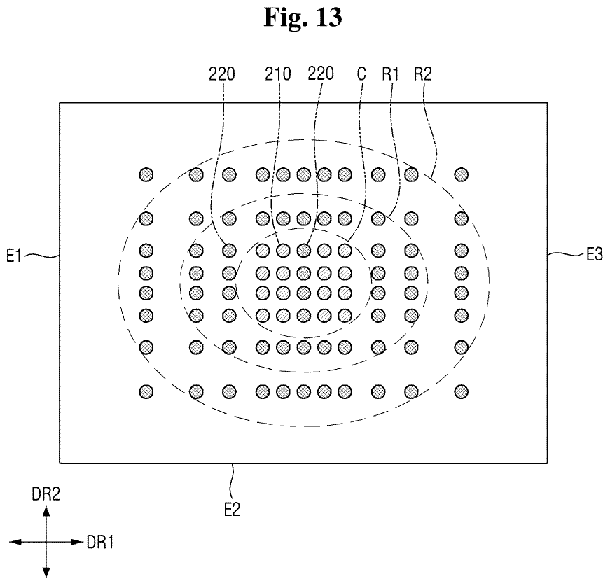

FIGS. 12 and 13 are views for describing a semiconductor device according to an example embodiment of the present disclosure.

First, referring to FIG. 12, the structure includes a center region C, a first peripheral region R1 surrounding the center region C, and a second peripheral region R2 surrounding the first peripheral region R1.

Two peripheral regions R1 and R2 surrounding the center region C have been illustrated in FIG. 12, but the number of peripheral regions may be one or be three or more.

In addition, it has been illustrated in FIG. 12 that the center region C and the peripheral regions R1 and R2 have a circular shape. Accordingly to some example embodiments, however, the center region C and the peripheral regions R1 and R2 may have a polygonal shape (e.g., a quadrangular shape, a hexagonal shape, or an octagonal shape).

In FIG. 13, the electrode patterns 210 and the alleviation patterns 220 are disposed in the center region C, the first peripheral region R1, and the second peripheral region R2 illustrated in FIG. 12.

As a distance from the center region C increases, an interval between adjacent alleviation patterns 220 increases. That is, an interval between adjacent alleviation patterns 220 in the second peripheral region R2 is greater than an interval between adjacent alleviation patterns 220 in the first peripheral region R1.

Intervals between the patterns 210 and 220 in the center region C may be the same as each other.

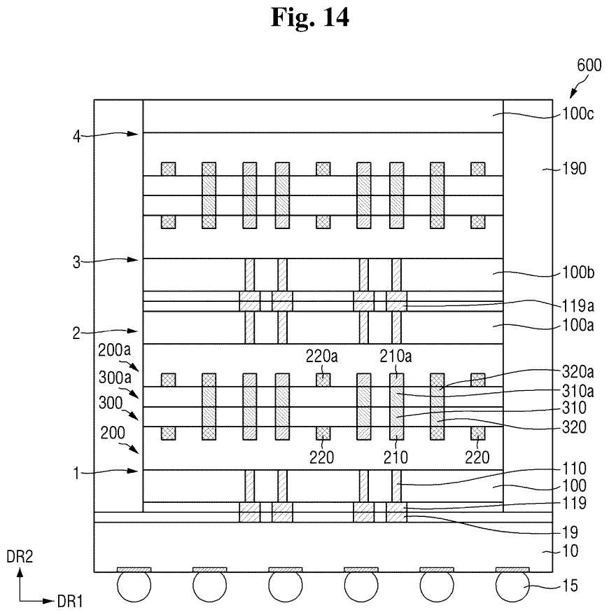

FIG. 14 is a view for describing a semiconductor package according to an example embodiment of the present disclosure. Hereinafter, a description of contents that are substantially the same as those described with reference to FIGS. 1 to 13 will be omitted.

Referring to FIG. 14, a semiconductor package 600 according to an example embodiment of the present disclosure includes a plurality of semiconductor devices 10, 1, 2, 3, and 4 that are sequentially stacked.

Each of the semiconductor devices 1, 2, 3, and 4 may be a memory chip, but example embodiments are not limited thereto. Each of the semiconductor device 1, 2, 3, and 4 may be a volatile memory semiconductor chip such as a dynamic random access memory (DRAM) or a static random access memory (SRAM) or a non-volatile memory semiconductor chip such as a phase-change random access memory (PRAM), a magnetoresistive random access memory (MRAM), a ferroelectric random access memory (FeRAM), or a resistive random access memory (RRAM).

The semiconductor device 10 may be a logic semiconductor chip. That is, the semiconductor device 10 may be a controller chip that controls operations such as input and output of the electrically connected semiconductor devices 1, 2, 3, and 4.

Connection terminals 15 are installed on a lower surface of the semiconductor device 10, and connection pads 19 are installed on an upper surface of the semiconductor device 10. Although not separately illustrated in FIG. 14, through silicon vias may be installed inside the semiconductor device 10.

As described with reference to FIGS. 1 and 2, the semiconductor device 1 includes a substrate 100, connection pads 119 installed on a lower surface of the substrate 100, a structure 200 formed on the substrate 100 and including multilayer metal patterns 210 and 220 and multilayer insulating layers, and a pad layer 300 formed on the structure 200 and including a plurality of bonding pads 310 and a plurality of dummy pads 320.

The semiconductor device 2 includes a substrate 100a, connection pads 119a installed on a lower surface of the substrate 100a, a structure 200a formed on the substrate 100a and including multilayer metal patterns 210a and 220a and multilayer insulating layers, and a pad layer 300a formed on the structure 200a and including a plurality of bonding pads 310a and a plurality of dummy pads 320a.

The semiconductor device 1 and the semiconductor device 2 may be bonded to each other through a hybrid bonding method. For example, the bonding pads 310 and/or the dummy pads 320 of the semiconductor device 1 and the bonding pads 310a and/or the dummy pads 320a of the semiconductor device 2 are bonded to each other. Further, a pad insulating film of the pad layer 300 of the semiconductor device 1 and a pad insulating film of the pad layer 300a of the semiconductor device 2 may be bonded to each other.

The semiconductor devices 3 and 4 also have a configuration and a connection relationship as that are substantially the same as those of the semiconductor devices 1 and 2.

A mold layer 190 may be formed on the upper surface of the semiconductor device 10 and side surfaces of the semiconductor devices 1, 2, 3, and 4. An upper surface of the uppermost semiconductor device 4 may be exposed without being covered by the mold layer 190, but example embodiments are not limited thereto.

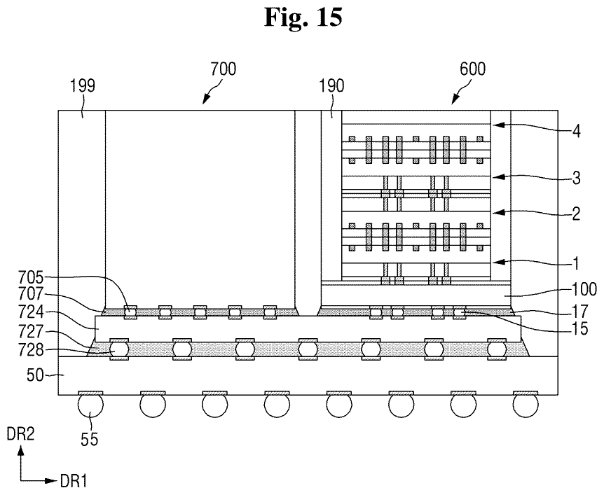

FIG. 15 is a view for describing a semiconductor package according to an example embodiment of the present disclosure. Hereinafter, a description of contents that are substantially the same as those described with reference to FIGS. 1 to 13 will be omitted.

Referring to FIG. 15, a semiconductor package according to an example embodiment of the present disclosure includes a substrate 50, an interposer 724, a semiconductor device 700, and a semiconductor device 600. The semiconductor device 600 is the semiconductor package described using FIG. 14.

The substrate 50 may be a package substrate. For example, the substrate 50 may be a printed circuit board (PCB) or a ceramic substrate. However, the present disclosure is not limited thereto. Connection terminals 55 are installed on a lower surface of the substrate 50.

The interposer 724 may be disposed on an upper surface of the substrate 50. The interposer 724 may be, for example, a silicon interposer, but example embodiments are not limited thereto. The interposer 724 may facilitate connection between the substrate 50 and the semiconductor devices 600 and 700 mounted on the interposer 724, and mitigate or prevent warpage of the semiconductor package.

Connection terminals 728 are installed below the interposer 724. An underfill material layer 727 may be disposed between the substrate 50 and the interposer 724. The underfill material layer 727 may surround the connection terminals 728. The underfill material layer 727 may mitigate or prevent the interposer 724 from being broken by fixing the interposer 724 onto the substrate 50. The underfill material layer 727 may include, for example, an insulating polymer material such as an epoxy molding compound (EMC), but example embodiments are not limited thereto.

Although not separately illustrated in FIG. 15, through-vias, redistribution patterns, and the like, may be installed in the interposer 724.

The semiconductor device 700 and the semiconductor device 600 are mounted on the interposer 724. Connection terminals 705 are installed between the interposer 724 and the semiconductor device 700, and connection terminals 15 are installed between the interposer 724 and the semiconductor device 600. An underfill material layer 707 may fill a space between the semiconductor device 700 and the interposer 724. An underfill material layer 17 may fill a space between the semiconductor device 600 and the interposer 724.

The connection terminals 55, 728, 705, and 15 may have various shapes such as a pillar structure, a ball structure, or a solder layer. For example, the connection terminals 55, 728, 705, and 15 may have the same size or have different sizes. For example, sizes of the connection terminals 705 and 15 may be substantially the same as each other and may be smaller than sizes of other connection terminals 55 and 728. A size of the connection terminal 728 may be smaller than a size of the connection terminal 55.

The semiconductor device 700 may be an integrated circuit (IC). For example, the semiconductor device 700 may be an application processor (AP) such as a central processing unit (CPU), a graphic processing unit (GPU), a field programmable gate array (FPGA), a digital signal processor, an encryption processor, a microprocessor, or a microcontroller, but example embodiments not limited thereto. For example, the semiconductor device 700 may be a logic chip such as an analog-to-digital converter (ADC) or an application-specific IC (ASIC) or may be a memory chip such as a volatile memory (e.g., a dynamic random access memory (DRAM)) or a non-volatile memory (e.g., a read only memory (ROM) or a flash memory).

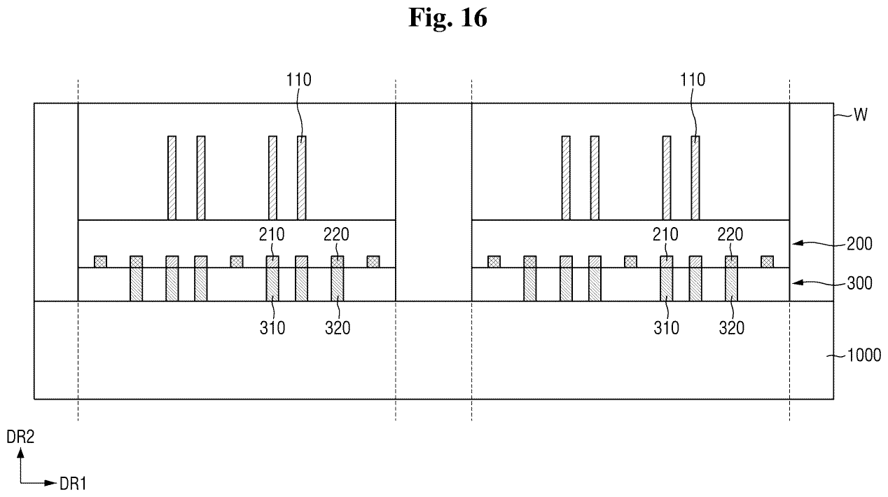

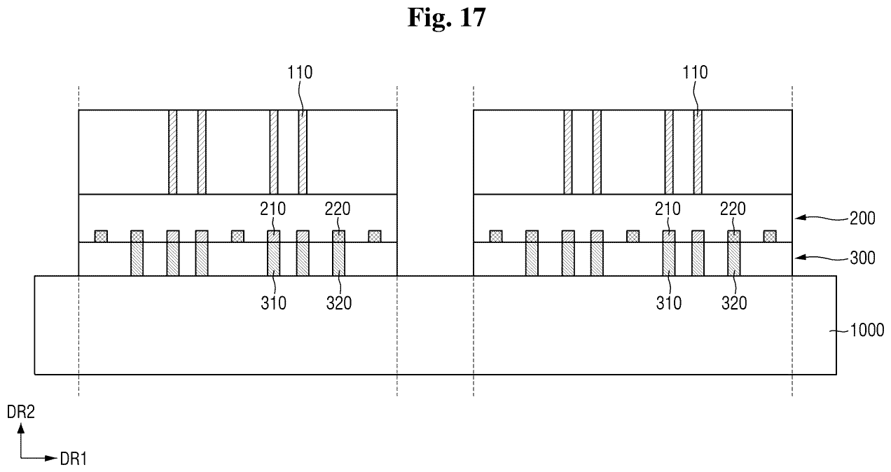

FIGS. 16 and 17 are intermediate step views for describing a semiconductor device according to an example embodiment of the present disclosure. Hereinafter, a description of contents that are substantially the same as those described with reference to FIGS. 1 and 2 will be omitted.

Referring to FIG. 16, a wafer W is formed on a carrier substrate 1000. The structure 200 and the pad layer 300 described above are formed in the wafer W, and the through silicon vias 110 are formed in the wafer W. However, this is before a thinning process is performed on the wafer W.

Referring to FIG. 17, the thinning process is performed on the wafer W, such that one ends of the through silicon vias 110 are exposed. An example of the thinning process may include a chemical mechanical polishing (CMP) process.

In an example embodiment of the present disclosure, the alleviation patterns 220 are installed in the structure 200, and thus, curvature in the topography of the wafer W may be alleviated even after the thinning process. Accordingly, curvature in topography of a semiconductor device formed by cutting the wafer W may be alleviated.

Subsequently, the wafer W is cut along a scribe line in chip units.

Subsequently, the cut chip is separated from the carrier substrate 1000.

Some example embodiments of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the example embodiments described above are illustrative rather than being restrictive in all aspects.

What is claimed is:

1. A semiconductor device comprising:
a substrate;
a structure on the substrate, the structure including multilayer metal patterns and multilayer insulating layers; and
a pad layer on the structure, the pad layer including a plurality of bonding pads,
wherein a plurality of uppermost patterns at an uppermost level among the multilayer metal patterns include electrode patterns configured to transfer signals and alleviation patterns configured to not transfer signals,
a first ratio of the alleviation patterns within a first reference shape at a first distance from an edge of the structure is greater than a second ratio of the alleviation patterns within a second reference shape at a second distance from the edge of the structure, and
the first distance is greater than the second distance.

2. The semiconductor device of claim 1, wherein
the pad layer further includes a plurality of dummy pads,
at least some of the electrode patterns are in direct contact with corresponding ones of the bonding pads, and
at least some of the alleviation pattern are in direct contact with corresponding ones of the dummy pads.

3. The semiconductor device of claim 1, wherein
the multilayer metal patterns includes the alleviation patterns at the uppermost level and metal patterns thereunder, and
the alleviation patterns are not electrically connected to the metal patterns.

4. The semiconductor device of claim 1, wherein
the first reference shape is a first rectangle, first four alleviation patterns among the alleviation patterns are at four corners of the first rectangle, and the first ratio is a ratio between a total area of the first rectangle and an area of the first four alleviation patterns within the first rectangle, and
the second reference shape is a second rectangle, second four alleviation patterns among the alleviation patterns are at four corners of the second rectangle, and the second ratio is a ratio between a total area of the second rectangle and an area of the second four alleviation patterns within the second rectangle.

5. The semiconductor device of claim 4, wherein
sizes of the first four alleviation patterns defining the first rectangle are same as sizes of the second four alleviation patterns defining the second rectangle, and
an area of the first rectangle is smaller than an area of the second rectangle.

6. The semiconductor device of claim 4, wherein
an area of the first rectangle are same as an area of the second rectangle, and
sizes of the first four alleviation patterns defining the first rectangle are greater than sizes of the second four alleviation patterns defining the second rectangle.

7. The semiconductor device of claim 4, wherein
a longitudinal length of the first rectangle is same as a longitudinal length of the second rectangle, and
a transverse length of the first rectangle is smaller than a transverse length of the second rectangle.

8. The semiconductor device of claim 1, wherein
the structure includes a center region and a first peripheral region surrounding the center region,
the electrode patterns are in the center region, and
a plurality of first alleviation patterns, among the alleviation patterns, are in the first peripheral region.

9. The semiconductor device of claim 8, wherein a third ratio of the electrode patterns within a third reference shape within the center region is greater than a fourth ratio of the first alleviation patterns within a fourth reference shape within the first peripheral region.

10. The semiconductor device of claim 9, wherein a difference between the third ratio and the fourth ratio is less than 53%.

11. The semiconductor device of claim 8, wherein
the structure further includes a second peripheral region surrounding the first peripheral region,
a plurality of second alleviation patterns, among the alleviation patterns, are in the second peripheral region, and
a fourth ratio of the alleviation patterns within a fourth reference shape within the first peripheral region is greater than a fifth ratio of the second alleviation patterns within a fifth reference shape within the second peripheral region.

12. The semiconductor device of claim 8, wherein the electrode patterns include a plurality of first electrode patterns on one side in the center region and a plurality of second electrode patterns on the opposite side in the center region, with respect to a plurality of second alleviation patterns therebetween.

13. The semiconductor device of claim 12, wherein a first interval between one of the first electrode patterns and one of the second alleviation patterns immediately adjacent thereto is same as a second interval between one of the second electrode patterns and one of the second alleviation patterns immediately adjacent thereto.

14. The semiconductor device of claim 1, wherein
the multilayer metal patterns includes the uppermost patterns and metal patterns thereunder, and
thicknesses of the uppermost patterns are greater than thicknesses of the metal patterns.

15. A semiconductor device comprising:
a substrate;
a structure on the substrate, the structure including multilayer metal patterns and multilayer insulating layers; and
a pad layer on the structure, the pad layer including a plurality of bonding pads,
wherein the structure includes a center region and a peripheral region surrounding the center region,
a plurality of uppermost patterns at an uppermost level among the multilayer metal patterns include a plurality of electrode patterns configured to transfer signals and a plurality of alleviation patterns configured to not transfer signals,
the plurality of electrode patterns include a plurality of first electrode patterns on one side and a plurality of second electrode patterns on the opposite side, with respect to a plurality of first alleviation patterns therebetween, the plurality of alleviation patterns including the first alleviation patterns,
the plurality of alleviation patterns include a plurality of second alleviation patterns in the peripheral region,
a first ratio of the first electrode patterns within a first reference shape in the center region is same as a second ratio of the second electrode patterns within a second reference shape in the center region, and
the first ratio of the first electrode patterns within the first reference shape in the center region is greater than a third ratio of the second alleviation patterns within a third reference shape in the peripheral region.

16. A semiconductor package comprising:
a first chip including a first bonding pad and a first pad insulating film surrounding the first bonding pad; and
a second chip including a second bonding pad and a second pad insulating film surrounding the second bonding pad,
wherein the first chip and the second chip are hybrid-bonded to each other such that the first bonding pad and the second bonding pad are in direct contact with each other and the first pad insulating film and the second pad insulating film are in direct contact with each other,
the first chip includes,
a substrate,
a structure on the substrate, the structure including multilayer metal patterns and multilayer insulating layers, and
a pad layer on the structure, the pad layer including a plurality of bonding pads,
a plurality of uppermost patterns at an uppermost level among the multilayer metal patterns include electrode patterns configured to transfer signals and alleviation patterns configured to not transfer signals,
a first ratio of the alleviation patterns within a first reference shape at a first distance from an edge of the structure is greater than a second ratio of the alleviation patterns within a second reference shape at a second distance from the edge of the structure, and
the first distance is greater than the second distance.

17. The semiconductor package of claim 16, wherein
the pad layer further includes a plurality of dummy pads,
at least some of the electrode patterns are in direct contact with corresponding ones of the bonding pads, and
at least some of the alleviation patterns are in direct contact with corresponding ones of the dummy pads.

18. The semiconductor package of claim 16, wherein
the first reference shape is a first rectangle and the second reference shape is a second rectangle,
sizes of four alleviation patterns forming the first rectangle are same as sizes of four alleviation patterns forming the second rectangle, and
an area of the first rectangle is smaller than an area of the second rectangle.

19. The semiconductor package of claim 16, wherein
the substrate includes a center region and a peripheral region surrounding the center region,
the electrode patterns are in the center region,
a plurality of first alleviation patterns, among the alleviation patterns, are in the peripheral region, and
a third ratio of the electrode patterns within a third reference shape within the center region is greater than a fourth ratio of the first alleviation patterns within a fourth reference shape within the peripheral region.

20. The semiconductor package of claim 19, wherein a difference between the third ratio and the fourth ratio is less than 53%.
